(19) United States
(12) Patent Application Publication
(10) Pub. No.: US 2021/0016417 A1
(43) Pub. Date: Jan. 21, 2021

(54) CMP PAD CONDITIONER AND METHOD FOR MANUFACTURING THE SAME

(71) Applicant: SHINHAN DIAMOND IND. CO., LTD., Incheon (KR)

(72) Inventors: Shin Kyung KIM, Seoul (KR); Sung Gyu KIM, Incheon (KR); Dong Youl PARK, Incheon (KR); Kang Joon KIM, Incheon (KR); Kyoung Jin KIM, Incheon (KR); Tae Hyeon KIM, Incheon (KR)

(21) Appl. No.: 16/929,481

(22) Filed: Jul. 15, 2020

(30) Foreign Application Priority Data
Jul. 15, 2019 (KR) 10-2019-0085209

(51) Int. Cl. B24B 53/017

(52) U.S. Cl. CPC B24B 53/017; H01L 21/30625

(57) ABSTRACT

A CMP pad conditioner and method for manufacturing the same. The CMP pad conditioner includes: a metal plate shank, diamond grit particles each having a lower end secured to a surface of the metal plate shank; a plating layer formed on the surface of the metal plate shank and surfaces of lower portions of the diamond grit particles to expose upper portions of the diamond grit particles; and a coating layer deposited over a surface of the plating layer and surfaces of the upper portions of the diamond grit particles.

### CROSS-REFERENCE TO RELATED APPLICATIONS

This application claims priority to Korean Application No. 10-2019-0085209, filed Jul. 15, 2019, which is incorporated herein by reference in its entirety.

### BACKGROUND

### Technical Field

The present disclosure relates to a CMP pad conditioner manufacturing method and a CMP pad conditioner manufactured by the same and, more particularly, to a CMP pad conditioner manufacturing method which can allow improvement in bonding strength of the diamond grit particles, improvement in environmental friendliness and corrosion and wear resistance of a CMP pad conditioner, acceleration of expansion of fine-line width semiconductor processes, and reduction in volume of electronic devices, and a CMP pad conditioner manufactured by the same.

### Description of the Related Art

Generally, a chemical mechanical polishing (CMP) process is used in many industrial fields to polish the surface of a specific workpiece.

In particular, in the field of manufacturing semiconductor devices, microelectronic devices, or computer products, a CMP process is widely used to polish ceramics, silicon, glass, quartz, metals, and/or wafers thereof.

A CMP process involves use of a CMP pad adapted to be rotated on a workpiece, such as a wafer. In a wafer polishing process, a liquid slurry containing chemicals and grit particles are added to the CMP pad.

A CMP pad conditioner is composed of a metal plate shank manufactured in a disk shape using a metal, multiple diamond grit particles coupled to a surface of the metal plate shank to polish a surface of a wafer, and a plating layer securing the diamond grit particles to the surface of the metal plate shank.

In manufacture of semiconductor device, scratches or defects formed on a wafer during a CMP process degrade yield and productivity of the semiconductor devices. Particularly, in a CMP process in which a relatively large diameter wafer is flattened using a correspondingly large CMP pad, large impact and stress are applied to the wafer and the CMP pad, thereby causing increase in frequency of occurrence of defects, such as scratches, on the wafer.

Typical CMP pad conditioners have a problem in that water used in a wafer polishing process penetrates a junction (interface) between a metal plate shank and each diamond grit particle, causing corrosion of a plating layer, which results in separation of the diamond grit particles from the metal plate shank and thus occurrence of scratches on the surface of the wafer.

As literature related to the present disclosure, Korean Patent No. 10-1131496 (Mar. 22, 2012) discloses a CMP pad conditioner and a method of manufacturing the same.

### BRIEF SUMMARY

Embodiments of the present disclosure provide a CMP pad conditioner manufacturing method in which one or multiple plating layers are formed at interfaces between a metal plate shank and diamond grit particles by a plating method and a coating layer is deposited to a predetermined thickness on surfaces of the plating layers and the diamond grit particles, thereby achieving improvement in bonding strength of the diamond grit particles, improvement in environmental friendliness and corrosion and wear resistance of a CMP pad conditioner, acceleration of expansion of fine-line width semiconductor processes, and reduction in volume of electronic devices, and a CMP pad conditioner manufactured by the same.

In addition, embodiments of the present disclosure provide a CMP pad conditioner manufacturing method in which formation of a coating layer is performed by a deposition method using a reactant having a gas phase, whereby the coating layer can be deposited over a large area or in a complex shape at a high synthesis rate, thereby facilitating manufacture of a CMP pad conditioner, and a CMP pad conditioner manufactured by the same.

In accordance with one embodiment of the present disclosure, a CMP pad conditioner manufacturing method includes: a mask layer formation step in which a mask layer having multiple insertion grooves is formed on a surface of a metal plate shank; a diamond grit particle placement step in which diamond grit particles are placed in the insertion grooves, respectively; a diamond grit particle securing step in which a setting plating portion is formed in the insertion grooves to secure lower portions of the diamond grit particles to the surface of the metal plate shank; a mask removal step in which the mask layer is removed from the surface of the metal plate shank to expose the setting plating portion and upper portions of the diamond grit particles; a plating layer formation step in which a plating layer is formed on the surface of the metal plate shank, a surface of the setting plating portion, and surfaces of the lower portions of the diamond grit particles with the upper portions of the diamond grit particles exposed; and a coating layer formation step in which a coating layer is deposited over a surface of the plating layer and surfaces of the exposed upper portions of the diamond grit particles.

In the coating layer formation step, the coating layer may be a diamond-like carbon (DLC) thin film.

In the coating layer formation step, the coating layer may be formed to a thickness of 0.1 μm to 5 μm.

In the plating layer formation step, the plating layer may include a single layer formed by plating nickel (Ni).

In the plating layer formation step, the plating layer may include two layers formed by sequentially plating nickel (Ni) and PNC (Pd+Ni+Cr).

In accordance with another embodiment of the present disclosure, a CMP pad conditioner includes: a metal plate shank; diamond grit particles each having a lower end secured to a surface of the metal plate shank; a plating layer formed on the surface of the metal plate shank and surfaces of lower portions of the diamond grit particles to expose upper portions of the diamond grit particles; and a coating layer deposited over a surface of the plating layer and surfaces of the upper portions of the diamond grit particles.

The CMP pad conditioner may further include: a setting plating portion formed on the surfaces of the lower portions of the diamond grit particles and the surface of the metal plate shank by a plating method, the setting plating portion being attached to the surface of the metal plate and the lower portions of the diamond grit particles to secure the diamond grit particles to the surface of the metal plate shank.

The plating layer may include a single layer formed by plating nickel (Ni). The plating layer may include two layers formed by sequentially plating nickel (Ni) and PNC (Pd+Ni+Cr).

According to the embodiments of the present disclosure, one or multiple plating layers are formed at interfaces between a metal plate shank and diamond grit particles by a plating method and a coating layer is deposited to a predetermined thickness on surfaces of the plating layers and the diamond grit particles, thereby achieving improvement in bonding strength of the diamond grit particles, improvement in environmental friendliness and corrosion and wear resistance of a CMP pad conditioner, acceleration of expansion of fine-line width semiconductor processes, and reduction in volume of electronic devices.

In addition, according to the embodiments of the present disclosure, formation of the coating layer is performed by a deposition method using a reactant having a gas phase, whereby the coating layer can be deposited over a large area or in a complex shape at a high synthesis rate, thereby facilitating manufacture of a CMP pad conditioner.

### BRIEF DESCRIPTION OF THE SEVERAL VIEWS OF THE DRAWINGS

The above and other objects, advantages and features of the present disclosure will become apparent from the detailed description of the following embodiments with reference to the accompanying drawings, in which:

FIG. 1 is a flowchart of a CMP pad conditioner manufacturing method according to the present disclosure;

FIG. 2 is a view showing a mask layer formation step of the CMP pad conditioner manufacturing method according to the present disclosure;

FIG. 3 is a view showing a grit particle placement step of the CMP pad conditioner manufacturing method according to the present disclosure;

FIG. 4 is a view showing a grit particle securing step of the CMP pad conditioner manufacturing method according to the present disclosure;

FIG. 5 is a view showing a mask removal step in the CMP pad conditioner manufacturing method according to the present disclosure;

FIG. 6 is a view showing a plating layer formation step of the CMP pad conditioner manufacturing method according to the present disclosure;

FIG. 7 is a view of a CMP pad conditioner manufactured through a coating layer formation step of the CMP pad conditioner manufacturing method according to the present disclosure; and

FIG. 8 is a bottom view of a CMP pad conditioner according to the present disclosure.

### DETAILED DESCRIPTION

Hereinafter, embodiments of the present disclosure will be described with reference to the accompanying drawings.

The above and other aspects, features, and advantages of the present disclosure will become apparent from the detailed description of the following embodiments in conjunction with the accompanying drawings.

It should be understood that the present disclosure is not limited to the following embodiments and may be embodied in different ways, and that the embodiments are provided for complete disclosure and thorough understanding of the present disclosure by those skilled in the art. The scope of the present disclosure is defined only by the claims.

Description of known functions and constructions which may unnecessarily obscure the subject matter of the present disclosure will be omitted.

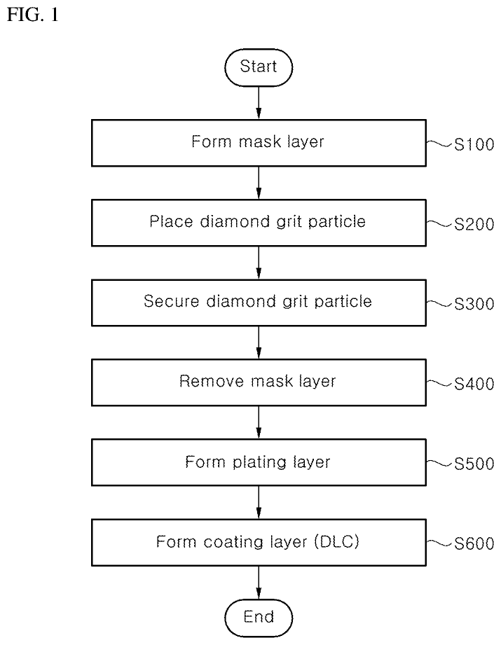

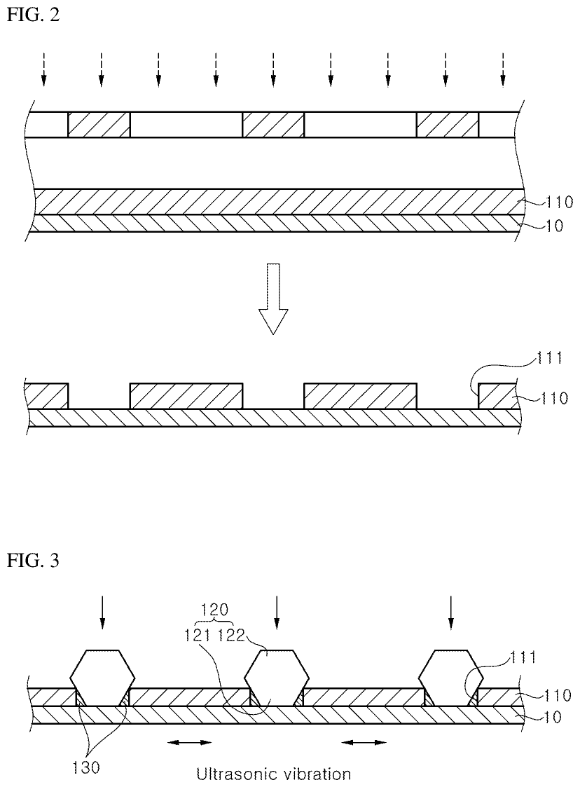

FIG. 1 is a flowchart of a CMP pad conditioner manufacturing method according to the present disclosure, FIG. 2 is a view showing a mask layer formation step of the CMP pad conditioner manufacturing method according to the present disclosure, and FIG. 3 is a view showing a grit particle placement step of the CMP pad conditioner manufacturing method according to the present disclosure.

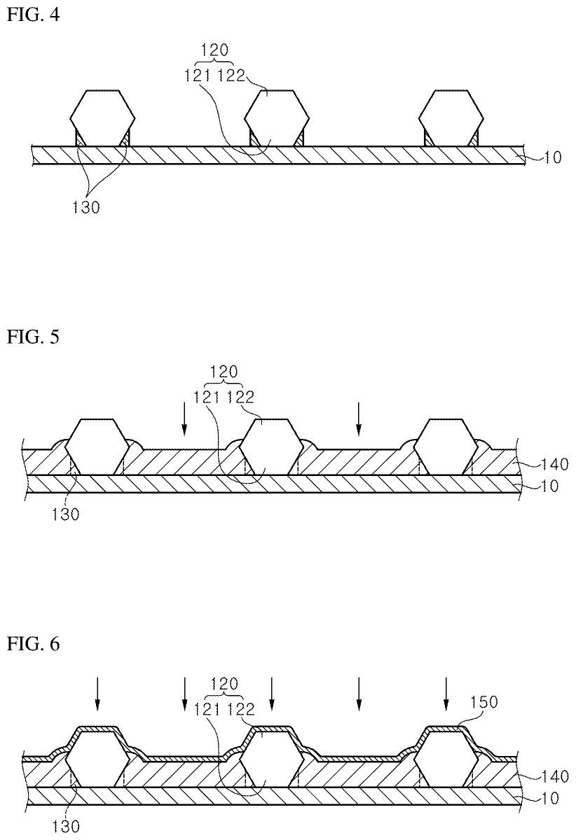

FIG. 4 is a view showing a grit particle securing step of the CMP pad conditioner manufacturing method according to the present disclosure, FIG. 5 is a view showing a mask removal step in the CMP pad conditioner manufacturing method according to the present disclosure, and FIG. 6 is a view showing a plating layer formation step of the CMP pad conditioner manufacturing method according to the present disclosure.

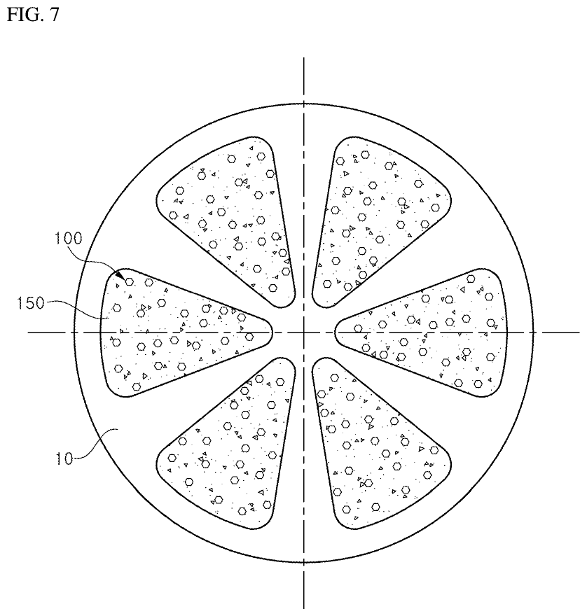

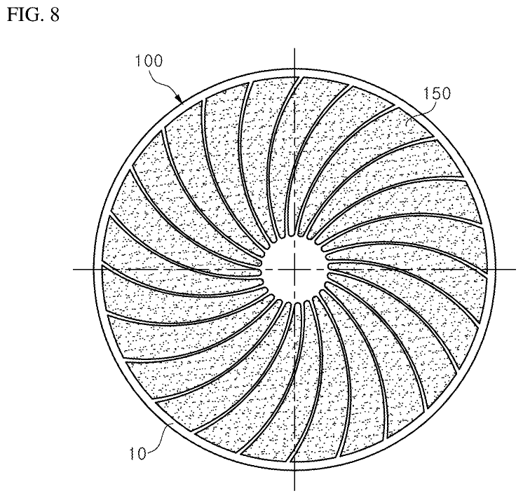

FIG. 7 is a view of a CMP pad conditioner manufactured through a coating layer formation step of the CMP pad conditioner manufacturing method according to the present disclosure, and FIG. 8 is a bottom view of a CMP pad conditioner according to the present disclosure.

Referring to FIG. 1 to FIG. 6, the CMP pad conditioner manufacturing method according to the present disclosure includes a mask layer formation step S100, a diamond grit particle placement step S200, a diamond grit particle securing step S300, a mask removal step S400, and a plating layer formation step S500, and a coating layer formation step S600.

First, in the mask layer formation step S100, a mask layer 110 having multiple insertion grooves 111 is formed on a surface of a metal plate shank 10, as shown in FIG. 2.

Here, the insertion grooves 111 are spaces into which diamond grit particles 120 described below are inserted, and the surface of the metal plate shank 10 is exposed through the insertion grooves 111.

In the mask layer formation step S100, the mask layer 110 is formed on the surface of the metal plate shank 10 to a predetermined thickness, wherein the metal plate shank 10 may be fabricated in a disc shape using a material, such as stainless steel.

Further, in the mask layer formation step S100, the mask layer 110 may be formed to a predetermined thickness by photo etching (lithography) or the like.

For example, the mask layer 110 may be subjected to an exposure process in which the mask layer is irradiated with light and a subsequent development process to have the multiple insertion grooves 111 through which the metal plate shank 10 is exposed upward.

Next, in the diamond grit particle placement step S200, multiple diamond grit particles 120 are placed in the insertion grooves 111, respectively, as shown in FIG. 3.

Specifically, in the diamond grit particle placement step S200, the diamond grit particles 120 may be placed in the insertion grooves 111, respectively, by placing the diamond grit particles 120 on the surface of the metal plate shank 10, followed by application of ultrasonic vibration to the metal plate shank 10.

Here, each of the diamond grit particles 120 may have a lower portion 121 inserted into the insertion groove 111 and an upper portion 122 protruding above the insertion groove 111.

In addition, the diamond grit particles 120 may have a particle diameter of 90 μm to 240 μm. However, it will be understood that the present disclosure is not limited thereto and the particle diameter of the diamond grit particles 120 may be varied, as needed.

Next, in the diamond grit particle securing step S300, a setting plating portion 130 is formed in the insertion grooves 110 to secure the lower portion 121 of each of the diamond grit particles 120 to the surface of the metal plate shank 10.

Here, the setting plating portion 130 is attached to both the lower portions 121 of the diamond grit particles 120, that is, lower edges of the diamond grit particles 120, and the surface of the metal plate shank 10 such that diamond grit particles 120 are securely held on the surface of the metal plate shank 10.

That is, with the setting plating portion 130, the diamond grit particles 120 can be held steady on the surface of the metal plate shank 10, whereby a polishing process can be performed with upper ends of the diamond grit particles 120 contacting a wafer.

Next, in the mask removal step S400, the mask layer 110 is removed from the surface of the metal plate shank to expose the setting plating portion 130 and the upper portions 122 of the diamond grit particles 120.

Here, the lower portions 121 of the diamond grit particles 120 remain securely attached to the surface of the metal plate shank 10 via the setting plating portion 130.

Next, in the plating layer formation step S500, a plating layer 140 is formed on surfaces of the metal plate shank 10, the setting plating portions 130, and the lower portions 121 of the diamond grit particles 120, with the upper portions 122 of the diamond grit particles 120 exposed.

In the plating layer formation step S500, the plating layer 140 is formed to cover the surface of the metal plate shank 10, the surface of the setting plating portion 130, and the lower portions 121 of the diamond grit particles 120. Here, the plating layer 140 covers the lower ends of the diamond grit particles 120.

In one embodiment, in the plating layer formation step S500, the plating layer 140 may include a single layer formed by plating nickel (Ni), as shown in FIG. 5. In another embodiment, in the plating layer formation step S500, the plating layer 140 may include two layers (not shown) formed by sequentially plating nickel (Ni) and PNC (Pd+Ni+Cr).

Here, PNC refers to a palladium-nickel-chrome mixture and the plating layer 140 may be formed by sequentially plating nickel (Ni) and PNC.

In a further embodiment, in the plating layer formation step S500, the plating layer 140 may include three layers (not shown) formed by sequentially plating nickel (Ni), PNC, and chrome (Cr).

Here, PNC refers to a palladium-nickel-chrome mixture and the plating layer 140 may be formed by sequentially plating nickel (Ni), PNC, and chrome (Cr).

Finally, in the coating layer formation step S600, a coating layer 150 is deposited over the plating layer 140 and surfaces of the exposed upper portions of the diamond grit particles 120.

Here, in the coating layer formation step S600, the coating layer 150 may be a diamond-like carbon (DLC) thin film and may be formed to a thickness of 0.1 μm to 5 μm.

DLC thin films have similar properties to diamond, and are also called “I-Carbon” in terms of the fact that the structure and properties thereof depend on activated ions used in synthesis thereof.

In addition, when containing hydrogen, DLC thin films are called “hydrogenated amorphous carbon” to emphasize structural characteristics thereof.

In this regard, DLC thin films are denoted by “a-C:H” as hydrogenated amorphous silicon is denoted by a-Si:H. Further, DLC thin films are also called “hard carbon,” “dense carbon,” and “dense hydrocarbon” in the sense of having high density and high hardness, and are also called “hydrogenated diamond-like carbon (HDLC)” and “diamond-like hydrocarbon (DLHC).”

DLC thin films are roughly divided into two types depending on whether they contain hydrogen or not. Particularly, a DLC thin film synthesized by synthesis methods using hydrocarbon compounds as a synthesis gas, such as plasma CVD, ECR, sputtering, and ion beam evaporation, has a high hydrogen content of 20% to 50%.

Among group IV elements, only carbon atoms can form all of sp¹ bonds, sp² bonds, and sp³ bonds. Graphite consists of only sp²-bonded carbon atoms, and diamond consists of only sp³-bonded carbon atoms. Materials composed of sp²-bonded carbon atoms and sp³-bonded carbon atoms mixed in an amorphous phase are collectively referred to as DLC films.

Characteristics of DLC thin films depend on hydrogen content thereof. A DLC thin film having a hydrogen content of less than 1% is referred to as an “amorphous carbon thin film (a-C).” Hydrogenated amorphous carbon thin films are divided into polymeric carbon thin films (hydrogen content: 50% or more) and DLC thin films (hydrogen content: 20% to 30%) according to hydrogen contents thereof.

DLC thin films have been widely used as wear-resistant coatings due to high hardness thereof, as well as used in the electronics industry due to insulating properties thereof, whereas polymeric carbon thin films have not been widely used yet.

Table 1 shows basic properties of such amorphous carbon thin films.

TABLE 1

| | Density | Hardness | | Hydrogen | Band gap |
|---|---|---|---|---|---|
| | (mg/cm³) | (GPa) | Sp³ (5) | (at. %) | (eV) |
| Diamond | 3.515 | 100 | 100 | | 5.5 |
| Graphite | 2.267 | | 0 | | ~0.04 |
| Glassy | 1.3-1.55 | 2-3 | −0 | | 0.01 |
| Carbon | | | | | |
| a-Carbon | 1.9-2.0 | 2-5 | 1 | | 0.4-0.7 |
| (evaporated) | | | | | |
| a-Carbon | 3.0 | 30-130 | 90 ± 5 | <9 | 0.5-1.5 |
| (MSIB) | | | | | |
| a-C:H | 1.6-2.2 | 10-20 | 30-60 | 10-40 | 0.8-1.7 |
| (hard) | | | | | |
| a-C:H | 0.9-1.6 | <5 | 50-80 | 40-65 | 1.6-4 |
| (soft) | | | | | |
| Polyethylene | 0.92 | 0.01 | 100 | 67 | 6 |

Since DLC thin films have similar properties to diamond and can be synthesized at a low temperature (from room temperature to 200° C.), various materials including paper, polymers, ceramics and the like can be used as a substrate therefor.

In particular, DLC carbon thin films have physical, chemical, and optical properties, such as high hardness and high lubricity, chemical stability, and bio-compatibility.

However, there are some problems that limit use of DLC thin films. Particularly, when subjected to high temperature, DLC thin films are unstable and have similar properties to graphite. In addition, synthesized DLC thin films have poor adhesion and a high residual compressive stress of up to 10 GPa.

For a relatively thin DLC film, residual compressive stress serves to suppress fracture of the film, whereas, for a relatively thick DLC film, residual compressive stress causes the film to peel off of a substrate.

Such a peeling phenomenon becomes severe under high-humidity conditions, causing use of DLC films to be feasible only under limited atmospheres. Therefore, it is necessary to solve these problems in order to expand application of DLC thin films.

Recently, many studies have been done to solve the problems of DLC films, such as low thermal stability and high residual compressive stress, through addition of elements, such as W, Ti, Ni, B, Si, and F.

The majority of the studies are focused on Si-doped DLC (Si-DLC) thin films, particularly Si-DLC thin films that can be deposited on various substrates and have low residual compressive stress, high hardness, high thermal stability, and high surface adhesion.

Such DLC thin film coatings have various advantages such as high wear resistance, low coefficient of friction, chemical stability, high transmittance and low reflectivity in the infrared region, high electrical resistance and low dielectric constant, and field emission characteristics.

Due to the fact that DLC thin films have these characteristics and process controllability via process parameters, DLC thin films can be applied to various fields. In early days, DLC thin films were mostly applied to wear/corrosion-resistant coatings and protective coatings, such as lubricant thin films, for automotive engines and tools.

Intense research on wear resistance has led to a novel VCR that uses a diamond head drum. Such a VCR head drum reads information from a videotape while rotating on the videotape at very high speed, causing a lot of wear thereon. Coating the head drum with a protective layer can improve lifespan and performance of the head drum.

In addition, many studies are conducted to use DLC as a protective coating suppressing surface destruction of optical fibers based on good acid/corrosion resistance of DLC. Recently, research is under way to use optical fibers as protective thin films for automotive headlights and displays by improving hydrophobicity/hydrophilicity, hardness, and transparency to visible light of the optical fibers through surface treatment and addition of hexamethyldisilazane (HMDS).

As synthesis methods for DLC thin film coatings, there have been mainly reported ion plating, which features a high deposition rate, and plasma CVD using DC or RF. In addition, in order to compensate for shortcomings of plasma CVD, various synthesis methods, such as sputtering using ECR, DC, RF, or ion beams, have been studied.

Although there are lots of studies focused on increase in deposition rate and improvement in properties of DLC thin film coatings, synthesis methods for DLC thin film coatings can be divided broadly into physical vapor deposition (PVD) and chemical vapor deposition (CVD).

PVD includes various methods such as evaporation, ion plating, and sputtering, and can increase the proportion of sp³-bonded carbon atoms through control over the ratio of carbon to hydrogen and ion energy, thereby achieving improvement in hardness of DLC thin film coatings.

CVD exhibits isotropic deposition characteristics and thus can be used in synthesis of a DLC thin film coating having a relatively complex shape. CVD technology using plasma, such as PECVD, has also been developed, and DLC thin films typically have a structure in which sp²-bonded carbon atoms and sp³-bonded carbon atoms are mixed.

A DLC thin film produced by PVD has higher stress concentration in the surface thereof than that produced by CVD, and thus can be deposited stably only to a limited thickness while requiring a relatively long time to deposit.

Next, a CMP pad conditioner 100 according to the present disclosure will be described with reference to FIG. 7 and FIG. 8. The CMP pad conditioner 100 according to the present disclosure includes a metal plate shank 10, diamond grit particles 120, a plating layer 140, and a coating layer 150.

The metal plate shank 10 may have a disc shape. Each of the diamond grit particles 120 has a lower end secured to a surface of the metal plate shank 10. A lower portion 121 of each of the diamond grit particles 120 may be inserted into an insertion groove 111 and an upper portion 122 of each of the diamond grit particles 120 may protrude above the insertion groove 111.

The plating layer 140 is formed on the surface of the metal plate shank 10 and surfaces of the lower portions 121 of the diamond grit particles 120 to expose the upper portions 122 of the diamond grit particles 120.

Here, the plating layer 140 may include a single layer formed by plating nickel (Ni), as shown in FIG. 5 and FIG. 6. However, it will be understood that the present disclosure is not limited thereto and the plating layer 140 may include two layers formed by sequentially plating nickel (Ni) and PNC (Pd+Ni+Cr) or may include three layers formed by sequentially plating nickel (Ni), PNC (Pd+Ni+Cr), and chromium (Cr).

Since the plating layer 140 is attached to the surface of the metal plate shank 10 to cover the lower portions 121 of the diamond grit particles 120, the diamond grit particles 120 can be more stably secured to the metal plate shank 10.

The CMP pad conditioner may further include a setting plating portion 130 formed on the surfaces of the lower portions 122 of the diamond grit particles 120 and the surface of the metal plate shank 10 by a plating method, as shown in FIG. 4.

Here, the setting plating portion 130 is attached to the surface of the metal plate shank 10 and the surfaces of the lower portions 121 of the diamond grit particles 120, thereby securing the diamond grit particles 120 to the surface of the metal plate shank 10.

The coating layer 150 is deposited over a surface of the plating layer 140 and surfaces of upper portions of the diamond grit particles 120. The coating layer 150 is preferably deposited as a diamond like carbon (DLC) thin film and may have a thickness of 0.1 μm to 5 μm.

For example, portions of the coating layer 150 which are deposited on upper ends of the diamond grit particles 120 may gradually wear out as the CMP pad conditioner is used in a wafer polishing process. Accordingly, after use for a certain period of time, the upper ends of the diamond grit particles 120 are exposed and side surfaces of the diamond grit particles 120 remain covered by the coating layer 150.

The coating layer 150 can prevent moisture from penetrating an interface between each of the diamond grit particles 120 and the metal plate shank 10 during wafer polishing.

According to the embodiments of the present disclosure, one or multiple plating layers 140 are formed at interfaces between a metal plate shank 10 and diamond grit particles 120 by a plating method and a coating layer 150 is deposited to a predetermined thickness over surfaces of the plating layers 140 and the diamond grit particles 120, thereby achieving improvement in bonding strength of the diamond grit particles 120, improvement in environmental friendliness and corrosion and wear resistance of a CMP pad conditioner, acceleration of expansion of fine-line width semiconductor processes, and thus reduction in volume of electronic devices.

In addition, according to the embodiments of the present disclosure, formation of the coating layer 150 is performed by a deposition method using a reactant having a gas phase, whereby the coating layer can be deposited over a large area or in a complex shape at a high synthesis rate, thereby facilitating manufacture of the CMP pad conditioner.

Although some embodiments of a CMP pad conditioner manufacturing method and a CMP pad conditioner manufactured by the same have been described herein, it should be understood that these embodiments may be embodied in a variety of other forms.

Therefore, the scope of the present disclosure is not limited to these embodiments and should be defined by the appended claims and equivalents thereto.

In other words, it should be understood that these embodiments are provided for illustration only and are not to be construed in any way as limiting the present disclosure, that the scope of the present disclosure is defined by the appended claims rather than by the detailed description, and that all changes or modifications derived from the spirit and scope of the claims and equivalent concepts thereto are construed as being included in the scope of the present disclosure.

1. A CMP pad conditioner manufacturing method, comprising:
a mask layer formation step in which a mask layer having multiple insertion grooves is formed on a surface of a metal plate shank;
a diamond grit particle placement step in which diamond grit particles are placed in the insertion grooves, respectively;
a diamond grit particle securing step in which a setting plating portion is formed in the insertion grooves to secure lower portions of the diamond grit particles to the surface of the metal plate shank;
a mask removal step in which the mask layer is removed from the surface of the metal plate shank to expose the setting plating portion and upper portions of the diamond grit particles;
a plating layer formation step in which a plating layer is formed on the surface of the metal plate shank, a surface of the setting plating portion, and surfaces of the lower portions of the diamond grit particles with the upper portions of the diamond grit particles exposed; and
a coating layer formation step in which a coating layer is deposited over a surface of the plating layer and surfaces of the exposed upper portions of the diamond grit particles.

2. The CMP pad conditioner manufacturing method according to claim 1, wherein, in the coating layer formation step, the coating layer is a diamond-like carbon (DLC) thin film.

3. The CMP pad conditioner manufacturing method according to claim 2, wherein, in the coating layer formation step, the coating layer is formed to a thickness of 0.1 μm to 5 μm.

4. The CMP pad conditioner manufacturing method according to claim 1, wherein, in the plating layer formation step, the plating layer comprises a single layer formed by plating nickel (Ni).

5. The CMP pad conditioner manufacturing method according to claim 1, wherein, in the plating layer formation step, the plating layer comprises two layers formed by sequentially plating nickel (Ni) and PNC (Pd+Ni+Cr).

6. The CMP pad conditioner manufacturing method according to claim 2, wherein, in the plating layer formation step, the plating layer comprises three layers formed by sequentially plating nickel (Ni), PNC (Pd+Ni+Cr), and chromium (Cr).

7. A CMP pad conditioner, comprising:
a metal plate shank,
diamond grit particles each having a lower end secured to a surface of the metal plate shank;
a plating layer formed on the surface of the metal plate shank and surfaces of lower portions of the diamond grit particles to expose upper portions of the diamond grit particles; and
a coating layer deposited over a surface of the plating layer and surfaces of the upper portions of the diamond grit particles.

8. The CMP pad conditioner according to claim 7, further comprising:
a setting plating portion formed on the surfaces of the lower portions of the diamond grit particles and the surface of the metal plate shank by a plating method, the setting plating portion being attached to the surface of the metal plate and the lower portions of the diamond grit particles to secure the diamond grit particles to the surface of the metal plate shank.

9. The CMP pad conditioner according to claim 7, wherein the plating layer comprises a single layer formed by plating nickel (Ni).

10. The CMP pad conditioner according to claim 7, wherein the plating layer comprises two layers formed by sequentially plating nickel (Ni) and PNC (Pd+Ni+Cr).

11. The CMP pad conditioner according to claim 7, wherein the plating layer comprises three layers formed by sequentially plating nickel (Ni), PNC (Pd+Ni+Cr), and chromium (Cr).
